(19) United States
(12) Patent Application Publication
(10) Pub. No.: US 2012/0134116 A1
(43) Pub. Date: May 31, 2012

(54) IMAGE FORMING APPARATUS

(75) Inventor: Akihiro Masaki, Osaka (JP)

(73) Assignee: KYOCERA MITA CORPORATION, Osaka (JP)

(21) Appl. No.: 13/305,094

(22) Filed: Nov. 28, 2011

(30) Foreign Application Priority Data
Nov. 30, 2010 (JP) 2010-267665

(51) Int. Cl. H05K 5/00

(52) U.S. Cl. 361/724

(57) ABSTRACT

The image forming apparatus includes: a cabinet main body including one or more of main body side walls formed to continue to the outer edges of the side face portion, and to extend toward the outer lateral face; a circuit board being attached to the outer lateral face in the side face portion, and being electrically connected to the side face portion; and an electrically conductive shielding case that is disposed to cover the circuit board, the shielding case including a top plate that having a first side on an outer edge and/or a second side continuing to the first side are connected to the main body side walls, and shielding case side walls, being connected to the side face portion, and being disposed to surround the circuit board in collaboration with the main body side walls.

This application is based on and claims the benefit of priority from Japanese Patent Application No. 2010-267665, filed on 30 Nov. 2010, the content of which is incorporated herein by reference.

### BACKGROUND OF THE DISCLOSURE

1. Field of the Disclosure

The present invention relates to an image forming apparatus.

2. Related Art

Conventionally, as an image forming apparatus such as a copying machine and a printer, a large number of image forming apparatuses include, an image forming unit that forms an image on a sheet of paper, a cabinet main body that accommodates the image forming unit, and a circuit board that is attached to an outside of the cabinet main body. Electronic components for controlling various members composing the image forming unit are mounted on the circuit board.

Among the electronic components mounted on the circuit board, predetermined electronic components such as an ASIC (Application Specific Integrated Circuit) including peripheral circuits become a factor for generating high frequency noise.

Here, there exists an image forming apparatus to which is attached a shielding sheet metal that entirely covers circuit board attached to a cabinet main body, for the purpose of suppressing propagation and radiation of high frequency noise generated from a predetermined electronic component and a circuit.

However, in such an instance, since a large sheet metal for covering a surface of the cabinet main body needs to be attached, there were cases where the cost of the image forming apparatus was increased, and the degree of freedom of the external design was decreased.

In contrast, there exists an image forming apparatus including a shielding case for shielding against high frequency noise that was generated.

For example, there has been proposed an image forming apparatus (Related Art 1), in which a circuit board (electric board) is disposed in a shielding box (housing) composed of noise shielding members, and the shielding box is configured to be replaceable.

However, since the image forming apparatus disclosed in Related Art 1 uses a shielding box composed of different members, the cost may be increased.

Here, in order to resolve the cost increase, there is also a structure (Related Art 2) in which, in place of a complete box, a box-like shielding member with one side open is attached to one side face of a cabinet main body.

However, in Related Art 2, an outer surface of the cabinet main body as a grounding member and a shielding case attached thereto form a shielding structure that is composed of two different members. As a result, there were cases where the shielding characteristics were not sufficient depending on the types of electronic components and the positions of mounting the electronic components. In such a shielding structure as well, the shielding characteristics are desired to be further improved.

### SUMMARY OF THE DISCLOSURE

An object of the present invention is to provide an image forming apparatus, having a shielding case that is disposed to cover a circuit board attached to a side face of a cabinet main body, which improves characteristics of shielding against high frequency noise that is generated from electronic components and circuits mounted on the circuit board. The present invention relates to an image forming apparatus including, an image forming unit that forms an image on a material for forming an image thereon, an electrically conductive cabinet main body that accommodates the image forming unit, the cabinet main body including a side face portion having an outer lateral face, and one or a plurality of main body side walls formed to continue to outer edges of the side face portion, and to extend toward the outer lateral face, a circuit board, on which a plurality of electronic components are mounted, the circuit board being attached to the outer lateral face in the side face portion, and being electrically connected to the side face portion; and an electrically conductive shielding case that is disposed to cover the circuit board, the shielding case including a top plate that is a substantially square top plate that is disposed to be spaced apart from the circuit board at a predetermined distance, wherein a first side on an outer edge and/or a second side continuing to the first side are connected to the main body side walls, and shielding case side walls, being formed to extend to the side face portion side by continuing to sides that are not connected to the main body side walls on outer edges of the top plate, being connected to the side face portion, and being disposed to surround the circuit board in collaboration with the main body side walls.

### BRIEF DESCRIPTION OF THE DRAWINGS

FIG. 1 is a view showing an arrangement of components of an image forming apparatus 1 as a first embodiment of the image forming apparatus of the present invention;

FIG. 2 is a perspective view showing a state in which a circuit board 600 is attached to a cabinet main body 110 in an apparatus main unit 105 of the image forming apparatus 1 of the first embodiment;

FIG. 3 is a perspective view showing a state in which a shielding case 700 is disposed to surround the circuit board 600 of the image forming apparatus 1 in the first embodiment;

FIG. 4 is a cross-sectional view along a line A-A in FIG. 3;

FIG. 5 is a cross-sectional view along a line B-B in FIG. 3;

FIG. 6 is a perspective view showing a state in which the circuit board 600 is attached to the cabinet main body 110 in the apparatus main unit 105 of the image forming apparatus 1 as a second embodiment of the image forming apparatus of the present invention; and

FIG. 7 is a perspective view showing a state in which the shielding case 700 is disposed to surround the circuit board 600 of the image forming apparatus 1 in the second embodiment.

### DETAILED DESCRIPTION OF THE DISCLOSURE

Embodiments of the present disclosure will be hereinafter described with reference to the attached drawings.

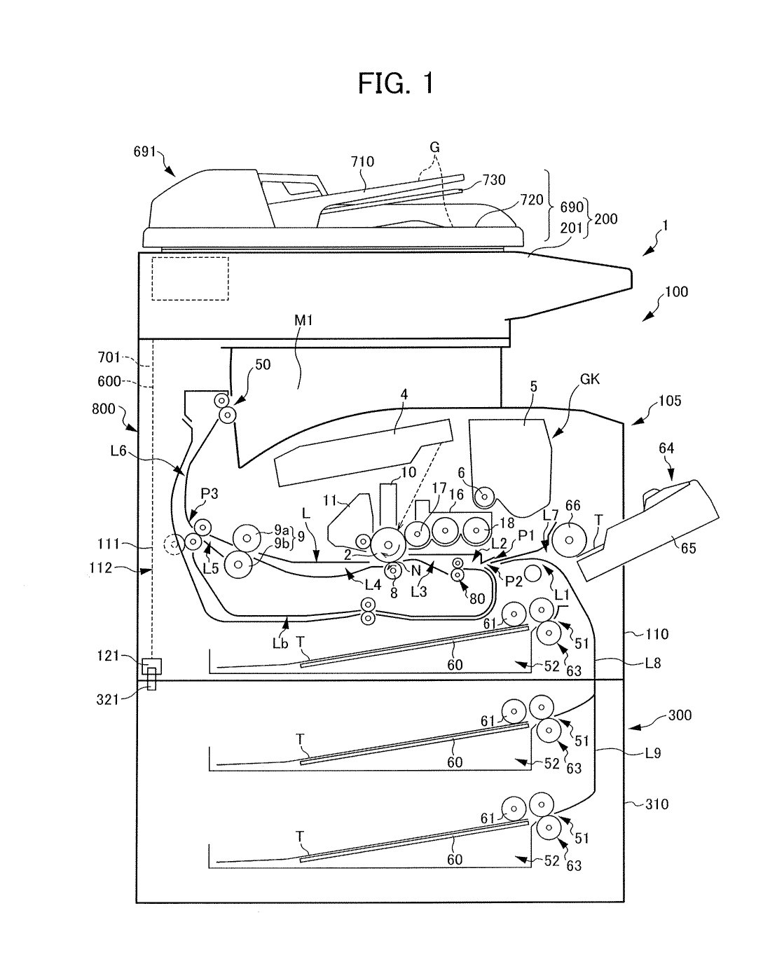

An entire structure of an image forming apparatus 1 as one embodiment of the image forming apparatus of the present disclosure will be described with reference to FIG. 1. FIG. 1 is a view showing an arrangement of components of the image forming apparatus 1 as a first embodiment of the image forming apparatus of the present disclosure.

As shown in FIG. 1, the image forming apparatus 1 of the present embodiment includes: an image forming apparatus main body 100; and an additional unit 300 (second housing) that is added to the image forming apparatus main body 100 by being disposed vertically below the image forming apparatus main body 100. The additional unit 300 accommodates sheets of paper T as a material for forming an image thereon, such that the sheets of paper T can be fed to a cabinet main body 110 (the image forming apparatus main body 100) to be described later. Based on a request by a user, the additional unit 300 is added to the image forming apparatus main body 100 as appropriate.

As shown in FIG. 1, the image forming apparatus main body 100 includes an image reading apparatus 200 and an apparatus main unit 105 (first housing).

The image reading apparatus 200 includes a reader unit 201 and a sheet material feeder 690. The sheet material feeder 690 is disposed vertically above the reader unit 201, and automatically conveys an original G (sheet material) to the reader unit 201.

As shown in FIG. 1, the sheet material feeder 690 includes a feed mechanism housing 691, an original placing portion 710, an original accumulating portion 720, and an intermediate tray 730.

The feed mechanism housing 691 accommodates a feed mechanism of the sheet material feeder 690.

The original placing portion 710 is a portion where an original G (sheet material) before scanning an image thereof is placed.

The original accumulating portion 720 is located vertically below the original placing portion 710, and accumulates originals G that have passed a predetermined reading position.

The intermediate tray 730 is disposed between the original placing portion 710 and the original accumulating portion 720, and divides a space between the original placing portion 710 and the original accumulating portion 720 into: a first space on the original accumulating portion 720 side; and a second space on the original placing portion 710 side.

The reader unit 201 includes: a lighting unit including a light source; a plurality of mirrors forming a light path; an imaging lens; a CCD as scanning means; and a CCD board that performs predetermined processing on image information scanned by the CCD, and outputs the image information to the apparatus main unit 105 side.

In the sheet material feeder 690, an image formed on the original G conveyed to the scanning position is scanned by the CCD.

As shown in FIG. 1, the apparatus main unit 105 is disposed vertically below the image reading apparatus 200 (the reader unit 201).

The apparatus main unit 105 has: an image forming unit GK that forms a image on a sheet of paper T based on image information; and a paper feeding/discharging portion that feeds the sheet of paper T to the image forming unit GK, and discharges the sheet of paper T on which the image has been formed.

Moreover, the apparatus main unit 105 has the cabinet main body 110 and an additional unit main body 310. The cabinet main body 110 is electrically conductive, configures an external shape of the apparatus main unit 105, and accommodates the image forming unit GK and the paper feeding/discharging portion.

A circuit board is attached to an outer surface (a back side in FIG. 1) of the cabinet main body 110 of the apparatus main unit 105, and a plurality of electronic components such as a CPU, memory and a clock and predetermined circuits are mounted on the circuit board. In addition, the cabinet main body 110 has an apparatus main unit side connector 121 that is electrically connected to the circuit board.

In addition, a design cover 800 made of resin is disposed on the outer surface of the cabinet main body 110, and forms the outer surface of the apparatus main unit 105.

The circuit board and the electronic components will be described later.

As shown in FIG. 1, the image forming unit GK includes a photosensitive drum 2, a charging unit 10, a laser scanner unit 4, a developing unit 16, a toner cartridge 5, a toner supply unit 6, a transfer roller 8, a drum cleaning unit 11, and a fixing unit 9 as a fixing part.

Furthermore, the paper feeding/discharging portion includes a paper feed cassette 52, a manual feed tray 65, a pair of registing rollers 80, and a conveyance path L of a sheet of paper T.

The photosensitive drum 2 is a cylindrical member, and functions as an image carrier. The photosensitive drum 2 is disposed in the apparatus main unit 105 so as to be rotatable around a rotational shaft that is perpendicular to the plane of FIG. 1. An electrostatic latent image is formed on the surface of the photosensitive drum 2.

The charging unit 10 is disposed vertically above the photosensitive drum 2. The charging unit 10 positively charges the surface of the photosensitive drum 2 uniformly (with positive polarity).

The laser scanner unit 4 is disposed vertically above the photosensitive drum 2 so as to be spaced apart from the photosensitive drum 2. The laser scanner unit 4 is composed of a laser light source, a polygon mirror, a polygon-mirror-driving motor and the like, none of which are illustrated in the drawings.

The laser scanner unit 4 scans and exposes the surface of the photosensitive drum 2 based on image information that is output from the image reading apparatus 200. By being scanned and exposed by the laser scanner unit 4, an electric charge, which has been charged on the surface of the photosensitive drum 2, is removed. As a result, an electrostatic latent image is formed on the surface of the photosensitive drum 2.

The developing unit 16 is disposed in front (right side in FIG. 1) of the photosensitive drum 2. The developing unit 16 develops an image of a single color toner (black toner in general) on an electrostatic latent image formed on the photosensitive drum 2. The developing unit 16 is composed of a developing roller 17 that can be disposed to face the photosensitive drum 2, and an agitation roller 18 for agitating toner.

The toner cartridge 5 stores toner to be supplied to the developing unit 16.

The toner supply unit 6 supplies the toner stored in the toner cartridge 5 to the developing unit 16.

The drum cleaning unit 11 is disposed left (left side in FIG. 1) the photosensitive drum 2. The drum cleaning unit 11 removes toner and attached matter remaining on the surface of the photosensitive drum 2.

The transfer roller 8 transfers a toner image, which has been developed on the surface of the photosensitive drum 2, directly onto a sheet of paper T. A voltage application unit (not shown) applies a transfer bias to the transfer roller 8 for transferring the toner image developed on the photosensitive drum 2 onto the sheet of paper T.

The toner image, which has been developed on the surface of the photosensitive drum 2, can be transferred onto the sheet of paper T via an intermediate transfer belt or the like.

The transfer roller 8 is configured to be movable between an abutting position to abut the photosensitive drum 2, and a separated position to be spaced apart from the photosensitive drum 2. More specifically, the transfer roller 8 is moved to the abutting position in a case in which the transfer roller 8 transfers a toner image, which has been developed on the surface of the photosensitive drum 2, onto a sheet of paper T; and the transfer roller 8 is moved to the separated position in other cases.

Here, the sheet of paper T is interposed between the photosensitive drum 2 and the transfer roller 8, and is pressed against the surface of the photosensitive drum 2 (the side where the toner image has been developed). In this way, a transfer nip N (transfer portion) is formed. The toner image developed on the photosensitive drum 2 is transferred onto the sheet of paper T in the transfer nip N.

By melting the toner that forms the toner image transferred onto the sheet of paper T, the fixing unit 9 fixes the toner on the sheet of paper T. The fixing unit 9 includes a heating roller 9a that is heated by a heater, and a pressing roller 9b that is pressed against the heating roller 9a. The sheet of paper T on which the toner image has been transferred is interposed between and conveyed by the heating roller 9a and the pressing roller 9b. As a result of the sheet of paper T being interposed and conveyed between the heating roller 9a and the pressing roller 9b, the toner transferred onto the sheet of paper T is melted and fixed on the surface of the sheet of paper T.

The paper cassette 52 is disposed in a bottom (vertically underneath) portion of the apparatus main unit 105. The paper cassette 52 is configured to be horizontally withdrawable to a front side (the plane of FIG. 1) of the apparatus main unit 105. The paper cassette 52 includes a placing board 60 for placing sheets of paper T. The paper cassette 52 stores the sheets of paper T stacked on the placing board 60. A cassette paper feed unit 51 is disposed at an end portion on a paper feeding side in the paper cassette 52 (an end portion on the right in FIG. 1). The cassette paper feed unit 51 feeds a sheet of paper T stored in the paper cassette 52 to the conveyance path L.

The cassette paper feed unit 51 includes a double-feed prevention mechanism that is composed of: a forward feed roller 61 that picks up the sheet of paper T placed on the placing board 60; and a pair of rollers 63 that feeds the sheet of paper T to the conveyance path L on a sheet by sheet basis.

The conveyance path L for conveying the sheets of paper T is formed between the cassette paper feed unit 51 or a manual paper feed unit 64 and the paper discharging unit 50. The conveyance path L has: a first conveyance path L1 from the cassette paper feed unit 51 to a first joining portion P1; a second conveyance path L2 from the first joining portion P1 to the pair of registing rollers 80; a third conveyance path L3 from the pair of registing rollers 80 to the transfer roller 8; a fourth conveyance path L4 from the transfer roller 8 to the fixing unit 9; a fifth conveyance path L5 from the fixing unit 9 to a branching portion P3; and a sixth conveyance path L6 from the branching portion P3 to the paper discharging unit 50.

Moreover, the conveyance path L has a seventh conveyance path L7 from the manual feed tray 65 to the first joining portion P1. The first joining portion P1 is a joining portion of the first conveyance path L1 that conveys the sheet of paper T from the cassette paper feed unit 51 and the seventh conveyance path L7 that conveys the sheet of paper T from the manual feed tray 65.

In addition, the conveyance path L of the present embodiment has a conveyance path L8 for the additional unit. The conveyance path L8 is formed to extend from the first conveyance path L1, which is from the cassette paper feed unit 51 to the first joining portion P1, to the additional unit 300 side. The conveyance path L8 conveys sheets of paper T fed from the additional unit 300 to the first conveyance path L1.

The additional unit 300 includes the paper cassettes 52 and 52 that are disposed in a vertical direction (so as to be two-tiered). The additional unit 300 includes the cassette paper feed units 51 and 51 that are disposed correspondingly to the paper cassettes 52 and 52, respectively. The additional unit 300 is connected to the cabinet main body 110 (the image forming apparatus main body 100) via a connecting mechanism that is not illustrated in the drawings.

The additional unit 300, which is connected to the cabinet main body 110 (the image forming apparatus main body 100), has an additional unit side connector 321 that receives, via the apparatus main unit side connector 121, power supplied from a power supply unit (not shown) on the cabinet main body 110 side, and a control signal transmitted from an image forming control unit (not shown).

Furthermore, the additional unit 300 has a liaison conveyance path L9 that conveys the sheets of paper T fed from the cassette paper feed units 51 and 51 to the conveyance path L8 for the additional unit on the apparatus main unit 105 side.

A second joining portion P2 is disposed somewhere along the second conveyance path L2. Furthermore, the conveyance path L has a returning conveyance path Lb that is formed to connect the branching portion P3 to the second joining portion P2. The second joining portion P2 is where the returning conveyance path Lb joins the second conveyance path L2.

Here, the pair of registing rollers 80 is disposed upstream in a direction of conveying the sheet of paper T in the transfer roller 8 (right side in FIG. 1). The pair of registing rollers 80 is a pair of rollers for correcting skew (diagonal paper feed) of the sheet of paper T, and for adjusting timing with respect to the formation of a toner image.

The returning conveyance path Lb is a conveyance path provided for the purpose of causing another surface (unprinted surface) opposite to a surface that has already been printed to face the photosensitive drum 2 when duplex printing is performed on the sheet of paper T.

By way of the returning conveyance path Lb, the sheet of paper T, which has been conveyed from the branching portion P3 the paper discharging unit 50 side, can be reversed and returned to the second conveyance path L2. The photosensitive drum 2 transfers a predetermined toner image onto an unprinted surface of the sheet of paper T that has been reversed through the returning conveyance path Lb.

The manual paper feed unit 64 is provided on a front face side of the cabinet main body 110 (right side in FIG. 1) and above the paper cassette 52. The manual paper feed unit 64 includes the manual feed tray 65 and a paper feed roller 66. A base end portion of the manual feed tray 65 is attached pivotably (openably and closably) to the vicinity of an entry to the seventh conveyance path 17. The manual feed tray 65 in the closed state composes a part of the front face of the cabinet main body 110. The paper feed roller 66 picks up a sheet of paper T placed on the manual feed tray 65, and feeds the sheet of paper T to the seventh conveyance path L7.

The manual paper feed unit 64 feeds the sheets of paper T placed on the manual feed tray 65 in the opened state to the second conveyance path 12 through the seventh conveyance path L7 and the first joining portion P1.

The paper discharging unit 50 is formed at the end portion of the sixth conveyance path 16. The paper discharging unit 50 is disposed at the upper portion of the apparatus main unit 105. The paper discharging unit 50 is open to the front side (right side in FIG. 1) of the apparatus main unit 105. The paper discharging unit 50 discharges the sheet of paper T, on which toner has been fixed by the fixing unit 9, to the outside of the apparatus main unit 105.

A discharged paper accumulating portion M1 is formed on an opening side of the paper discharging unit 50. The discharged paper accumulating portion M1 is formed on a top face (outer face) of the apparatus main unit 105. The discharged paper accumulating portion M1 is where the top face of the apparatus main unit 105 is formed to be recessed downward (vertically downward). A bottom face of the discharged paper accumulating portion M1 composes a part of the top face of the apparatus main unit 105. The sheet of paper T, on which a predetermined image has been formed and which has been discharged from the paper discharging unit 50, is stacked and accumulated on the discharged paper collecting section M1.

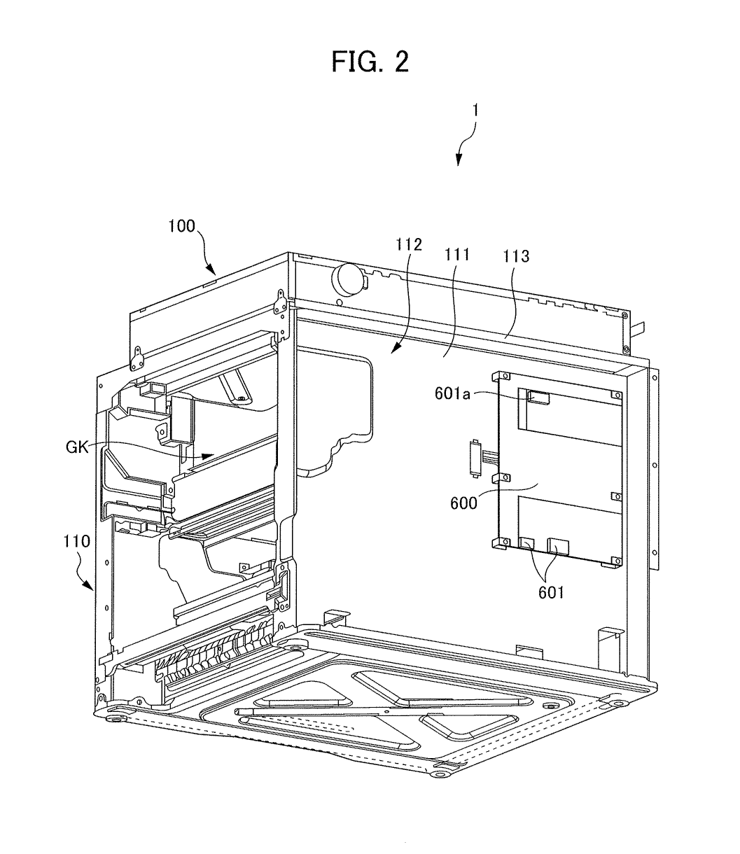

Next, a configuration according to a circuit board 600 and a shielding case 700 in the image forming apparatus 1 of the first embodiment will be described with reference to FIGS. 2 to 5.

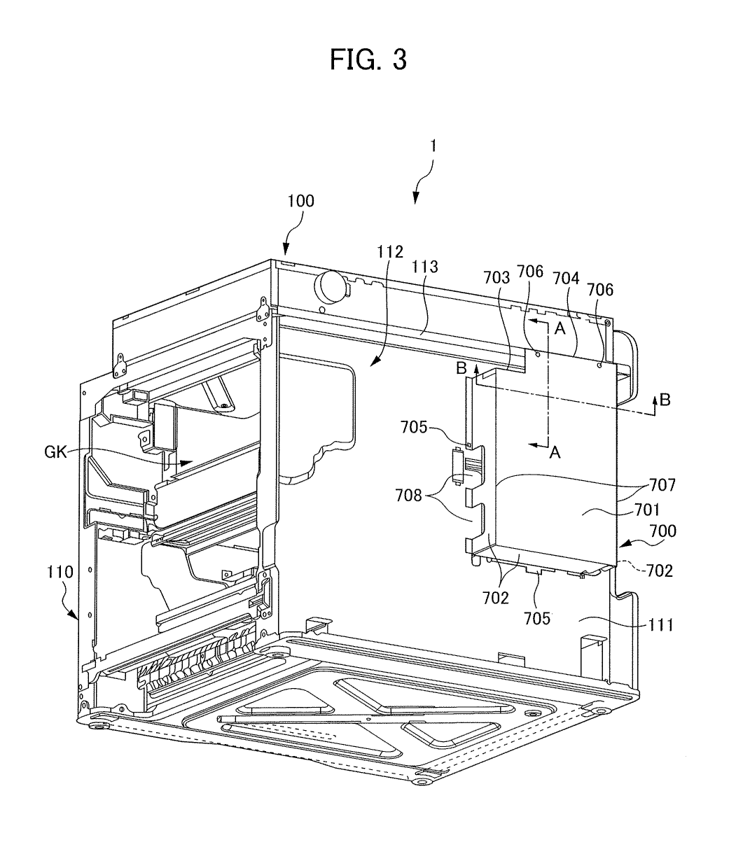

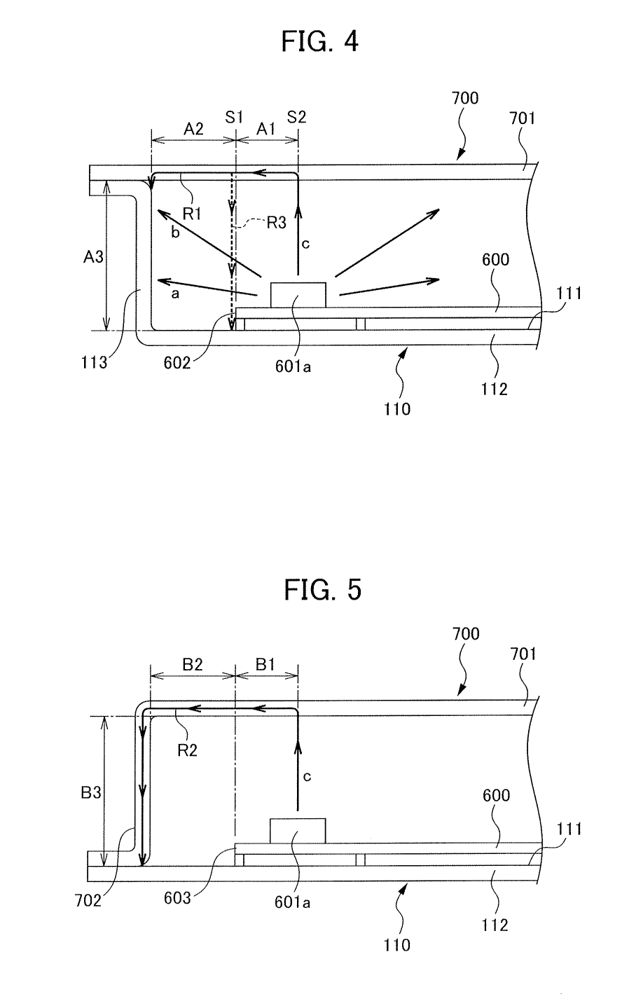

FIG. 2 is a perspective view showing a state in which the circuit board 600 is attached to the cabinet main body 110 in the apparatus main unit 105. FIG. 3 is a perspective view showing a state in which the shielding case 700 is disposed to surround the circuit board 600. FIG. 4 is a cross-sectional view along a line A-A in FIG. 3. FIG. 5 is a cross-sectional view along a line B-B in FIG. 3.

As shown in FIGS. 2 and 3, the cabinet main body 110 of the apparatus main unit 105 is a cabinet that forms an external shape of the apparatus main unit 105. As described above, the cabinet main body 110 accommodates the image forming unit GK and the paper feeding/discharging portion.

The cabinet main body 110 has a side face portion 112 and a main body side wall 113. The side face portion 112 is substantially square and has an outer lateral face 111. The main body side wall 113 continues to an outer edge (outer edge in the upper side in FIGS. 2 and 3) of the side face portion 112. In the present embodiment, the main body side wall 113 is formed by bending a portion corresponding to the outer edge on the vertically upper side in the side face portion 112 to extend (protrude) to the outer lateral face 111 side.

Here, in the present embodiment, the main body side wall 113 and the side face portion 112 serve as a grounding member (to be described later) that catches high frequency noise.

The circuit board 600 is attached to the outer lateral face 111 of the side face portion 112 of the cabinet main body 110. As a result, the circuit board 600 is electrically connected to the side face portion 112 of the cabinet main body 110.

A plurality of electronic components 601 are mounted on the circuit board 600. The plurality of electronic components 601 include, for example, a predetermined electronic component 601a and a circuit such as an ASIC (Application Specific Integrated Circuit), which become a factor for radiating high frequency noise. The predetermined electronic component 601a and the circuit such as an ASIC, which become a factor for radiating high frequency noise, are preferably disposed to a side that is closer to the main body side wall 113 in the circuit board 600 (see FIG. 4).

As shown in FIG. 3, the shielding case 700 is disposed to cover the circuit board 600. The shielding case 700 is disposed in the vicinity of one corner of the side face 112 of the rear face (back side in FIG. 1) of the cabinet main body 110, the corner being closer to the main body side wall 113. The shielding case 700 is formed of a conductive material. The shielding case 700 is formed by, for example, processing a metal plate or the like.

The shielding case 700 has a top plate 701 and shielding case side walls 702. The top plate 701 is a substantially square top plate that is disposed to be spaced apart from the circuit board 600 at a predetermined distance. The top plate 701 is disposed to be parallel with the side face portion 112.

The top plate 701 has an extended top plate 704, which is formed on an upper side (first side) 703, and which extends in parallel with the side face portion 112 toward the main body side wall 113 side. The extended top plate 704 is formed integrally with other portions of the top plate 701. The extended top plate 704 is connected to the main body side wall 113 of the cabinet main body 110 by way of screws 706. The top plate 701 is formed as a flat surface including the extended top plate 704.

The shielding case side walls 702 extend to the side face portion 112 of the cabinet main body 110, so as to continue from three edges that are not fixedly connected to the main body side wall 113, among the outer edges of the top plate 701 of the shielding case 700. The shielding case side walls 702, 702 and 702 are fixedly connected to the side face portion 112 of the cabinet main body 110 by way of screws 705, and are disposed to surround the entire perimeter of the circuit board 600 in collaboration with the main body side wall 113. Here, in the present embodiment, the main body side wall 113 is positioned on the side where the shielding case side walls 702 of the shielding case 700 are not formed, and functions as a side wall that surrounds the perimeter of the circuit board 600, in place of the shielding case side walls 702.

Moreover, among the shielding case side walls 702, 702 and 702, some of the shielding case side walls 702 are notched to form openings 708 for inserting electric wiring and the like.

Here, a positional relationship regarding the main body side wall 113 of the cabinet main body 110, the circuit board 600 (outer edge), the electronic component 601a mounted on the circuit board 600, etc. is preferably set as follows.

As shown in FIG. 4, a shortest distance A2 from a first corresponding position S1, which corresponds to an outer edge 602 on the main body side wall 113 side of the circuit board 600 in the top plate 701, to the main body side wall 113 is preferably shorter than a distance (height) A3 from the first corresponding position S1 to the outer lateral face 111 of the side face portion 112 of the cabinet main body 110. In other words, it is preferable to set the relationship to A2<A3.

In addition, as shown in FIGS. 4 and 5, a shortest distance (total distance A) A1+A2 from a second corresponding position S2, which corresponds to the predetermined electronic component 601a in the top plate 701, to the main body side wall 113 is preferably shorter than a shortest distance (total distance B) B1+B2+B3 from the second corresponding position S2 to the outer lateral face 111 of the side face portion 112 of the cabinet main body 110, through the top plate 701 and the shielding case side walls 702. In other words, it is preferable to set the relationship to A1+A2<B1+B2+B3.

Next, in the image forming apparatus 1 having the cabinet main body 110, the circuit board 600 and the shielding case 700, of which distance relationship is set as described above, the effects of shielding against high frequency noise radiated from the predetermined electronic component 601a and the circuit mounted on the circuit board 600 will be described.

As shown by an arrow in FIG. 4, the predetermined electronic component 601a and the circuit radiate high frequency noise in all directions. Among the noise, high frequency noise radiated in directions of arrows a and b are directly caught (shielded) by way of the main body side wall 113 that is a grounding member of the cabinet main body 110.

Furthermore, high frequency noise radiated in a direction of an arrow c is caught by way of the top plate 701 of the shielding case 700, thereafter passes through a route R1 including the extended top plate 704 of the top plate 701, and flows into (or is returned to and shielded by way of) the main body side wall (grounding portion) 113 of the cabinet main body 110.

Here, the route R1, where the high frequency noise flows into the grounding member in the extended top plate 704, is connected to the main body side wall (grounding portion) 113 by way of the screws 706, at a distance of A1+A2. In conventional cases in which a box-shaped shielding case is used, in which the side wall is in contact with or adjacent to the outer edge 602 of the circuit board 600, the shortest distance A1+A2 of the route R1 is shorter than a shortest distance A1+A3 of a route R3 for high frequency noise shown with a doted line in FIG. 4. In other words, as compared to the conventional cases, impedance in the route R1 in the present embodiment is lower by a distance difference Δ (A3−A2) between the routes R1 and R3.

Moreover, as shown in FIG. 5, the high frequency noise radiated from the predetermined electronic component 601a and the circuit in the direction of the arrow c is caught by way of the top plate 701, and thereafter, some of the high frequency noise flows through the top plate 701 toward the shielding case side walls 702 sides (route R2).

Here, the shortest distance (the total distance A) A1+A2 of the route R1 for high frequency noise in the present embodiment is set shorter than the shortest distance (the total distance B) B1+B2+B3 of the route R2 for high frequency noise; therefore, impedance in the route R1 is lower than impedance in the route R2. As a result, the high frequency noise caught by way of the top plate 701 scarcely flows toward the route R2 with higher impedance, but is gathered toward the route R1 with lower impedance, and flows into (or is returned to and shielded by way of) the main body side wall (grounding portion) 113 of the cabinet main body 110.

According to the image forming apparatus 1 of the first embodiment, for example, the following effects are achieved.

The image forming apparatus 1 of the present embodiment includes the circuit board 600 and the shielding case 700. The plurality of electronic components 601 and 601a are mounted on the circuit board 600 that is electrically connected (grounded) to the outer lateral face 111 of the side face portion 112 of the electrically conductive cabinet main body 110. The electrically conductive shielding case 700 is disposed to cover the circuit board 600. The shielding case 700 has the top plate 701 and the shielding case side walls 702. The top plate 701 with a substantially square shape is disposed to be spaced apart from the circuit board 600 at a predetermined distance. The first side 703 on the outer edge continues to the side face portion 112 of the cabinet main body 110, and is connected to the main body side wall 113 extending toward the outer lateral face 111 side. The shielding case side walls 702 are formed to extend toward the side face portion 112 side by continuing to the edge of the top plate 701, which is not connected to the main body side wall 113, and the shielding case side walls 702 are connected to the side face portion 112.

As a result, most of high frequency noise radiated from the electronic component 601a and the circuit is directly caught by way of the main body side wall 113 of the cabinet main body 110, which is grounded in the same way as circuit board 600. Since the main body side wall 113 as the grounding member directly catches high-frequency noise radiated from the electronic component 610a, the image forming apparatus 1 of the present embodiment improves the function of shielding against high frequency noise.

Moreover, high frequency noise, which is radiated from the electronic component 601a toward the top plate 701, can flow into (be returned to) the main body side wall 113 via the route R1 through the top plate 701, the impedance in the route R1 being lower than the impedance in conventional configurations of a shielding box. As a result, the image forming apparatus 1 of the present embodiment further improves the function of shielding against high frequency noise.

In addition, the shielding case 700 itself does not have to be formed in a box-like shape, and at least one edge side on the outer edge (a portion corresponding to a side wall opposite to the main body side face) is open. As a result, since the shielding case side wall on this edge side can become unnecessary, the manufacturing of the shielding case 700 can be facilitated, and the manufacturing cost can be reduced.

Furthermore, in the present embodiment, the shortest distance A1+A2 of the route R1 for high frequency noise in the top plate 701 is set shorter than the shortest distance A1+A3 of the route R3 for high frequency noise. As a result, the image forming apparatus 1 can provide the route (R1) having low impedance for high frequency noise. Moreover, as a result, the image forming apparatus 1 can further improve the shielding characteristics by suppressing unnecessary radiation of high frequency noise.

In addition, in the present embodiment, the shortest distance A1 A2 (total distance A) of the route R1 for high frequency noise is set shorter than the shortest distance B1+B2+B3 (total distance B) of the route R2 for high frequency noise. Accordingly, the impedance in the route R1 is lower than the impedance in the route R2. As a result, the image forming apparatus 1 can provide the route (R1) having low impedance for high frequency noise. Moreover, as a result, the image forming apparatus 1 can further improve the shielding characteristics by suppressing unnecessary radiation of high frequency noise.

Furthermore, in the present embodiment, the main body side wall 113 is formed by bending the outer edge side of the side face portion 112 of the cabinet main body 110. Accordingly, the main body side wall 113 and the side face portion 112, which have no connecting members such as joints or screws therebetween, serve as the same grounding member. Therefore, the impedance in the main body side wall 113 is further lowered. As a result, the shielding characteristics in the image forming apparatus 1 are further improved.

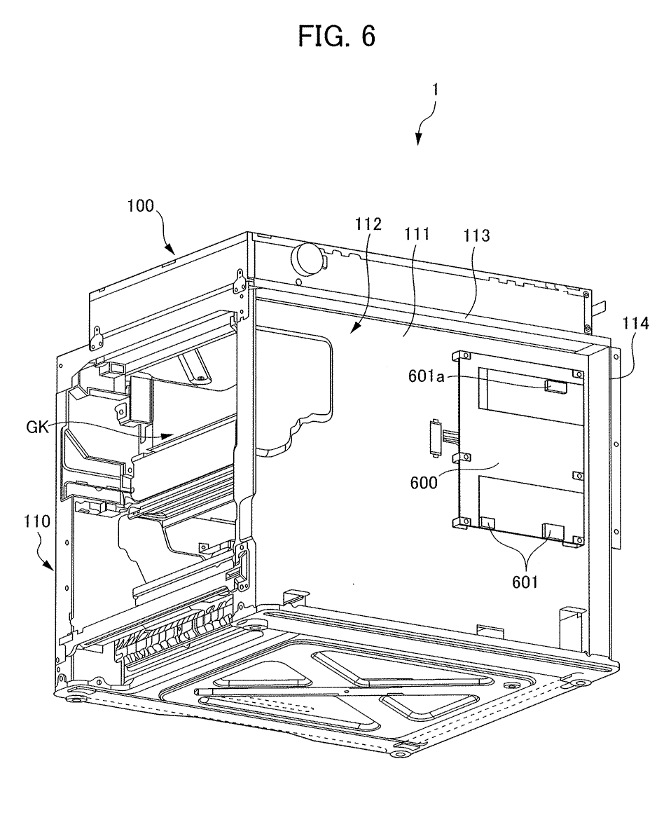

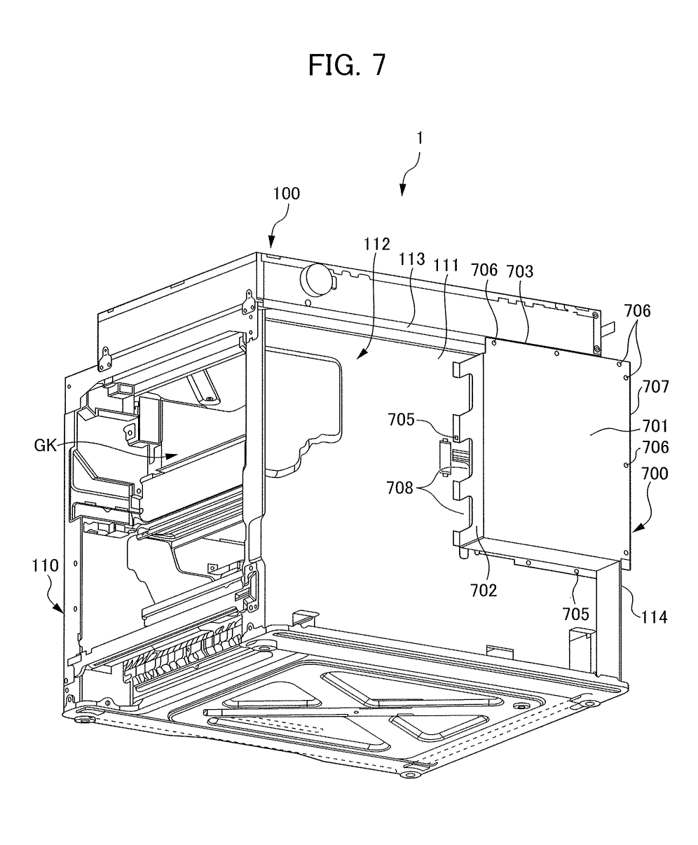

Next, a second embodiment of the present invention will be described with reference to FIGS. 6 and 7.

FIG. 6 is a perspective view showing a state in which the circuit board 600 is attached to the cabinet main body 110 in the apparatus main unit 105 of the image forming apparatus 1 as the second embodiment of the image forming apparatus of the present invention. FIG. 7 is a perspective view showing a state in which the shielding case 700 is disposed to surround the circuit board 600 of the image forming apparatus 1 in the second embodiment.

Regarding the second embodiment, points different from those of the first embodiment will be mainly described, and detailed descriptions of configurations similar to those of the first embodiment are omitted by assigning the same reference numerals thereto. The descriptions and drawings of the first embodiment are appropriately applied to or employed in points in the second embodiment that are not described and illustrated in particular.

As shown in FIG. 6, in the second embodiment, the cabinet main body 110 in the apparatus main unit 105 has: the side face portion 112 having a substantially square shape and having the outer lateral face 111; the (first) main body side wall 113 that continues to an outer edge on the vertically upper side of the side face portion 112; and a (second) main body side wall 114 that continues to an outer edge on the horizontally right side of the side face portion 112.

The main body side wall 113 and the main body side wall 114 are formed by bending the outer edge on the vertically upper side and the edge on the horizontally right side of the side face portion 112 to extend to the outer lateral face 111 side. The main body side wall 113 and the main body side wall 114 as well as the side face portion 112 serve as a grounding member (to be described later) that catches high frequency noise.

The circuit board 600 is attached to the outer lateral face 111 of the side face portion 112 of the cabinet main body 110. As a result, the circuit board 600 is electrically connected to the side face portion 112 of the cabinet main body 110.

A plurality of electronic components 601 are mounted on the circuit board 600. The plurality of electronic components 601 includes a predetermined electronic component 601a such as, for example, an electronic clock, which radiates high frequency noise.

As shown in FIG. 6, the predetermined electronic component 601a such as an electronic clock that radiates high frequency noise is preferably disposed to a side that is closer to the main body side wall 113 and the main body side wall 114 in the circuit board 600.

As shown in FIG. 7, the shielding case 700 is disposed to cover the circuit board 600. On the side face 112 of the cabinet main body 110, the shielding case 700 is disposed in the vicinity of one corner formed by the main body side wall 113 and the main body side wall 114.

The top plate 701 is a substantially square top plate that is disposed to be spaced apart from the circuit board 600 at a predetermined distance. The top plate 701 is disposed to be parallel with the side face portion 112. The top plate 701 is formed as a flat surface. The top plate 701 is formed in a substantially square shape, the entirety of which is a flat surface being parallel with the side face portion 112.

On the outer edge of the top plate 701, the upper side 703 (first side) and a right longitudinal side 707 (second side) continuing to the upper side 703 are connected to the main body side wall 113 and the main body side wall 114 of the cabinet main body 110 by way of screws 706, respectively.

The shielding case side walls 702 extend to the side face portion 112 of the cabinet main body 110, so as to continue from two sides that are not fixedly connected to the main body side wall 113 and the main body side wall 114, among the outer edges of the top plate 701 of the shielding case 700.

The shielding case side walls 702 and 702 are fixedly connected to the side face portion 112 of the cabinet main body 110 by way of the screws 705, and are disposed to surround the entire perimeter of the circuit board 600 in collaboration with the main body side wall 113 and the main body side wall 114.

It should be noted that, among the side faces, a side face of the upper side 703 of the top plate 701, and a side face of the right longitudinal side 707 continuing to the upper side 703 are open.

Here, in the present embodiment, the main body side wall 113 and the main body side wall 114 are positioned on the side where the shielding case side walls 702 and 702 of the shielding case 700 are not formed, and function as side walls that surround the perimeter of the circuit board 600, in place of the shielding case side walls 702.

Moreover, among the shielding case side walls 702 and 702, some of the shielding case side walls 702 are notched to form openings 708 for inserting electric wiring and the like from the inside to the outside.

According to the image forming apparatus 1 of the second embodiment, for example, the following effects are achieved, in addition to the effects described above in the first embodiment.

In the second embodiment, the upper side 703 and the right longitudinal side 707 of the top plate 701 of the shielding case 700 are connected to the main body side walls 113 and 114 of the cabinet main body 110. As a result, the main body side wall 113 and the main body side wall 114 being two side walls of the cabinet main body 110 function as a part of the shielding case 700.

The image forming apparatus 1 of the second embodiment has the two main body side walls that directly catch high frequency noise radiated from the electronic component 601a.

Furthermore, in addition to the route passing through the main body side wall 113 as the route having the short total distance in the first embodiment, the image forming apparatus 1 of the second embodiment can provide a route passing through the main body side wall 114.

As a result, the shielding function of the image forming apparatus 1 in the second embodiment is further improved.

Moreover, in the second embodiment, the shielding case 700 itself does not have to be formed in a box-like shape, and the two sides on the outer edges (portions corresponding to side walls opposite to the main body side wall 113 and the main body side wall 114) are open. As a result, since the shielding case side walls on these two sides can become unnecessary, the manufacturing of the shielding case 700 can be further facilitated, and the manufacturing cost can be further reduced.

Although preferred embodiments have been described above, the present invention is not limited to the aforementioned embodiments, and can be carried out in various modes.

The type of the image forming apparatus of the present invention is not limited in particular, and may be a copying machine, a printer, a facsimile, a multi-function device thereof, or the like.

The sheet-like material for forming an image thereon is not limited to a sheet of paper, and may be, for example, a film sheet.

Moreover, on the outside of the shielding case 700, the image forming apparatus may include the design cover 800 made of resin (see FIG. 1) that faces the outer surface of the top plate 701 and faces the outer lateral face 111 of the side face portion 112.

A part of the design cover 800 is placed on the outer surface of the top plate 701 of the shielding case 700, and another part of the design cover 800 is disposed to face the side face portion 112 and to cover the side face portion 112.

It is favorable that the top plate 701 of the shielding case 700 is disposed along a flat surface that connects the top edges of the main body side walls facing each other, since the design cover 800 can be favorably disposed.

In a case in which the design cover 800 is provided, the image forming apparatus 1 can harmonize the cost reduction and the external design improvement by combining the design cover 800 and the shielding case 700.

What is claimed is:

1. An image forming apparatus, comprising:
an image forming unit that forms an image on a material for forming an image thereon;
an electrically conductive cabinet main body that accommodates the image forming unit, the cabinet main body including
a side face portion having an outer lateral face, and
one or more of main body side walls formed to continue to outer edges of the side face portion, and to extend toward the outer lateral face;
a circuit board, on which a plurality of electronic components are mounted, the circuit board being attached to the outer lateral face in the side face portion, and being electrically connected to the side face portion; and
an electrically conductive shielding case that is disposed to cover the circuit board, the shielding case including
a top plate that is a substantially square top plate that is disposed to be spaced apart from the circuit board, wherein a first side on an outer edge and/or a second side continuing to the first side are connected to the main body side walls, and
shielding case side walls, being formed to extend to the side face portion side by continuing to sides that are not connected to the main body side walls on outer edges of the top plate, being connected to the side face portion, and being disposed to surround the circuit board in collaboration with the main body side walls.

2. The image forming apparatus according to claim 1, wherein
a side face on the first side and/or the second side in the shielding case is open.

3. The image forming apparatus according to claim 1, wherein
the circuit board includes a electronic component and a circuit serving as a factor for radiating high frequency noise, and
the electronic component and the circuit are disposed on the main body side wall side in the circuit board.

4. The image forming apparatus according to claim 3, wherein
a shortest distance from a first corresponding position, which corresponds to an outer edge of the main body side wall side of the circuit board in the top plate, to the main body side wall is shorter than a distance from the first corresponding position to the outer lateral face in the side face portion.

5. The image forming apparatus according to claim 3, wherein
a shortest distance from a second corresponding position, which corresponds to the electronic component and/or the circuit in the top plate, to the main body side wall is shorter than a shortest distance from the second corresponding position to the outer lateral face of the side face portion through the top plate and the shielding case side wall.

6. The image forming apparatus according to claim 1, wherein
the top plate includes an extended portion formed on the first side and/or the second side.

7. The image forming apparatus according to claim 6, wherein
the top plate is formed integrally with the extended portion, and is disposed in parallel with the side face portion.

8. The image forming apparatus according to claim 7, wherein
the top plate is formed in a shape of a flat surface including the extended portion.

9. The image forming apparatus according to claim 1, wherein
the first side and the second side of the top plate are connected to the main body side walls, and are disposed in parallel with the side face portion.

10. The image forming apparatus according to claim 9, wherein
the top plate is formed in a shape of a flat surface including the extended portion.

11. The image forming apparatus according to claim 1, wherein
the main body side wall is formed by bending an outer edge side in the side face portion.

12. The image forming apparatus according to claim 1, wherein
a design cover is provided on an outside of the shielding case, the design cover facing an outer face of the top plate, and being disposed to face the outer lateral face of the side face portion.
